(19) United States
(12) Patent Application Publication
(10) Pub. No.: US 2012/0112159 A1
(43) Pub. Date: May 10, 2012

(54) NITRIDE SEMICONDUCTOR LIGHT EMITTING ELEMENT

(75) Inventor: Satoshi KOMADA, Osaka-shi (JP)

(73) Assignee: Sharp Kabushiki Kaisha, Osaka-shi (JP)

(21) Appl. No.: 13/274,872

(22) Filed: Oct. 17, 2011

(30) Foreign Application Priority Data
Nov. 8, 2010 (JP) 2010-249390

(51) Int. Cl. H01L 33/04

(52) U.S. Cl. 257/13; 257/E33.008

(57) ABSTRACT

A nitride semiconductor light emitting element includes: an n type nitride semiconductor layer formed on a substrate; a light emitting layer formed on the n type nitride semiconductor layer; and a p type nitride semiconductor layer formed on the light emitting layer. The n type nitride semiconductor layer is constituted by one layer or two or more stacked layers. At least one layer constituting the n type nitride semiconductor layer contains Si and Sn as n type dopants and contains In as an isoelectronic dopant.

This nonprovisional application is based on Japanese Patent Application No. 2010-249390 filed on Nov. 8, 2010 with the Japan Patent Office, the entire contents of which are hereby incorporated by reference.

### BACKGROUND OF THE INVENTION

1. Field of the Invention

The present invention relates to a nitride semiconductor light emitting element, in particular, a nitride semiconductor light emitting element used for a light emitting diode (LED), a laser diode (LD), an electronic device, or the like.

2. Description of the Background Art

A nitride semiconductor used for a nitride semiconductor light emitting element or the like is required to have increased crystallinity in order to reduce operation voltage. In order to increase the crystallinity thereof, it is necessary to reduce lattice defects in the nitride semiconductor to reduce hole density of the nitride semiconductor.

For reduced hole density in such a nitride semiconductor, each of Japanese Patent Laying-Open No. 05-243614 (Patent Literature 1) and PHYSICAL REVIEW B, VOLUME 64, 035318 (Non-Patent Literature 1) discloses an art of adding an isoelectronic dopant to the nitride semiconductor, for example. In these literatures, a nitride semiconductor such as GaN is doped with an element of the same group, such as In, having an atomic radius larger than that of an element constituting the nitride semiconductor.

By doping with such an isoelectronic dopant, compressive stress is applied to the nitride semiconductor to cancel tensile strain in the nitride semiconductor, thereby achieving reduced hole density. In this way, the nitride semiconductor is provided with increased crystallinity, thus improving dislocation pinning and mobility.

### SUMMARY OF THE INVENTION

The above-described isoelectronic doping with In or the like provides reduced degree of supersaturation of holes, which leads to reduced hole density. An n type dopant used in the nitride semiconductor is Si, which substitutes Ga. However, a difference therebetween in boiling point causes change in surface energy and a difference therebetween in atomic radius causes generation of strains. Accordingly, if doped at a concentration of not less than 1×10¹⁹/cm³, periodicity in crystal of the nitride semiconductor is deteriorated, which results in deteriorated crystallinity, disadvantageously.

In view of the foregoing problem, the present invention has its object to increase crystallinity in a nitride semiconductor by containing Si, Sn, and In simultaneously as dopants in order to reduce operation voltage of a nitride semiconductor light emitting element.

A nitride semiconductor light emitting element of the present invention includes: an n type nitride semiconductor layer formed on a substrate; a light emitting layer formed on the n type nitride semiconductor layer; and a p type nitride semiconductor layer formed on the light emitting layer, the n type nitride semiconductor layer being constituted by one layer or two or more stacked layers, at least one layer constituting the n type nitride semiconductor layer containing Si and Sn as n type dopants and containing In as an isoelectronic dopant.

Preferably, the at least one layer constituting the n type nitride semiconductor layer contains Si at an atomic concentration of not less than 5×10¹⁸/cm³ and not more than 1×10²⁰/cm³, contains Sn at an atomic concentration of not less than 5×10¹⁷/cm³ and not more than 1×10¹⁹/cm³, and contains In at an atomic concentration of not less than 5×10¹⁹/cm³ and not more than 1×10²¹/cm³.

Preferably, the at least one layer constituting the n type nitride semiconductor layer contains Sn at an atomic concentration smaller than that of Si. Preferably, the at least one layer constituting the n type nitride semiconductor layer is GaN.

Preferably, the n type nitride semiconductor layer is a contact layer in contact with an n-side electrode. Preferably, the n-side electrode is made of a metal containing one or both of Ti and Al, or is made of an alloy containing the metal.

Preferably, the n type nitride semiconductor layer includes a first n type nitride semiconductor layer, and a second n type nitride semiconductor layer formed between the first n type nitride semiconductor layer and the light emitting layer, and the second n type nitride semiconductor layer contains the n type dopants at atomic concentrations smaller than those of the n type dopants contained in the first n type nitride semiconductor layer.

Preferably, the second n type nitride semiconductor layer contains In as an isoelectronic dopant. Further, the second n type nitride semiconductor layer preferably contains Mg. Preferably, the second n type nitride semiconductor layer contains Mg at an atomic concentration of not less than 5×10¹⁸/cm³ and not more than 1×10²⁰/cm³.

The nitride semiconductor light emitting element configured as above in the present invention achieves increased crystallinity in the nitride semiconductor, which leads to reduced operation voltage in the nitride semiconductor light emitting element.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view showing an exemplary basic structure of a nitride semiconductor light emitting element of the present invention.

FIG. 2 is a schematic cross sectional view showing a structure of a nitride semiconductor light emitting element of an example.

### DESCRIPTION OF THE PREFERRED EMBODIMENTS

The following describes an embodiment of the present invention with reference to figures. It should be noted that in the below-mentioned figures, the same or corresponding portions are given the same reference characters and are not described repeatedly. It should be also noted that dimensions in the figures such as lengths, sizes, and widths are appropriately modified to clarify and simplify the illustration and therefore do not represent actual dimensions.

(Nitride Semiconductor Light Emitting Element)

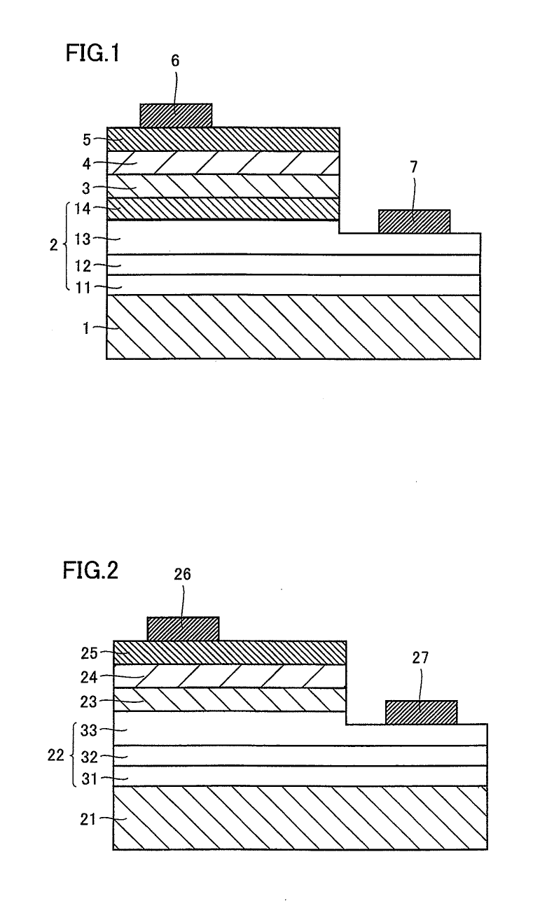

FIG. 1 is a schematic cross sectional view showing a structure of a nitride semiconductor light emitting element of the present invention. As shown in FIG. 1, the nitride semiconductor light emitting element of the present invention includes: an n type nitride semiconductor layer 2 formed on a substrate 1; a light emitting layer 3 formed on n type nitride semiconductor layer 2; and a p type nitride semiconductor layer 4 formed on light emitting layer 3. N type nitride semiconductor layer 2 is constituted by one layer or two or more stacked layers. At least one layer constituting n type nitride semiconductor layer 2 contains Si and Sn as n type dopants and contains In as an isoelectronic dopant.

By doping the at least one layer of the n type nitride semiconductor layer 2 with Si, Sn, and In simultaneously, tensile strain component and compressive strain component of crystallinity thereof are canceled, thereby achieving increased crystallinity. The following describes respective parts constituting the nitride semiconductor light emitting element of the present invention.

(Substrate)

In the present invention, an insulating substrate such as sapphire or a conductive substrate such as GaN, SiC, spinel, or ZnO can be used as substrate 1. Such a substrate 1 is not necessarily limited to a substrate with a flat surface. Substrate 1 may have a surface having irregularities formed thereon.

(N Type Nitride Semiconductor Layer)

The present invention is characterized in that the at least one layer constituting n type nitride semiconductor layer 2 contains Si and Sn as n type dopants, and contains In as an isoelectronic dopant.

By doping the at least one layer constituting n type nitride semiconductor layer 2 with Si, Sn, and In simultaneously, in particular, by doping the at least one layer with Si having an atomic radius smaller than that of Ga and Sn having an atomic radius larger than that of Ga simultaneously, a tensile strain component and a compressive strain component in the crystallinity are canceled to result in increased crystallinity. Accordingly, even with a high doping concentration of 5×10¹⁸/cm³ or greater, GaN having a high mobility of 100 cm²/Vs or greater can be obtained. Here, Si has its atomic radius of 0.54 Å, Ga has its atomic radius of 0.76 Å, and Sn has its atomic radius of 0.83 Å.

Further, the at least one layer constituting n type nitride semiconductor layer 2 contains In as the isoelectronic dopant, thereby reducing a degree of supersaturation of holes (i.e., thereby restraining generation of holes). This leads to increased crystallinity.

The above-described at least one layer constituting n type nitride semiconductor layer 2 preferably contains Si at an atomic concentration of not less than 5×10¹⁸/cm³and not more than 1×10²⁰/cm³, preferably contains Sn at an atomic concentration of not less than 5×10¹⁷/cm³ and not more than 1×10¹⁹/cm³, and preferably contains In at an atomic concentration of not less than 5×10¹⁹/cm³ and not more than 1×10²¹/cm³. If the atomic concentrations thereof exceed the upper limits of the numerical ranges respectively, the crystallinity may be deteriorated. On the other hand, if the atomic concentrations fall below the lower limits thereof, the effect of increasing the crystallinity cannot be attained sufficiently. Hence, both the cases are not preferable.

In such at least one layer constituting n type nitride semiconductor layer 2, it is preferable that the atomic concentration of Sn is smaller than that of Si. In this way, the crystallinity of n type nitride semiconductor layer 2 can be increased more. The at least one layer constituting n type nitride semiconductor layer 2 is preferably a nitride semiconductor containing one of Al, In, and Ga, and is more preferably GaN.

On n type nitride semiconductor layer 2, an n-side electrode 7 is formed. Here, n type nitride semiconductor layer 2 is preferably a contact layer in contact with n-side electrode 7. Because n type nitride semiconductor layer 2 is thus in contact with n-side electrode 7, carrier concentration becomes high to result in reduced contact resistance.

N type nitride semiconductor layer 2 may be constituted by a single layer or a multilayer structure. In the case where n type nitride semiconductor layer 2 is constituted by a multilayer structure, it is preferable to provide nitride semiconductor layers or superlattice layers different in composition or doping concentration. A preferable, exemplary multilayer structure is constituted by a low-temperature buffer layer 11, an undoped layer 12 made of GaN, an n type high-doped layer made of GaN, and an n type low-doped layer made of GaN as shown in FIG. 1. Here, the n type high-doped layer is defined as a first n type nitride semiconductor layer 13, whereas the n type low-doped layer is defined as a second n type nitride semiconductor layer 14.

In FIG. 1, n type nitride semiconductor layer 2 includes first n type nitride semiconductor layer 13, and second n type nitride semiconductor layer 14 provided between the first n type nitride semiconductor layer and light emitting layer 3. The atomic concentrations of the n type dopants in second n type nitride semiconductor layer 14 are smaller than those of the n type dopants contained in first n type nitride semiconductor layer 13.

Thus, second n type nitride semiconductor layer 14 having the n type dopants at the atomic concentrations smaller than those of the n type dopants contained in first n type nitride semiconductor layer 13 is provided just below light emitting layer 3. In this way, the n type low-doped layer having high crystallinity is introduced just below light emitting layer 3, which directly contributes to light emitting efficiency. Accordingly, the light emitting efficiency can be increased.

Further, second n type nitride semiconductor layer 14 may be undoped as long as the atomic concentration of Si is 5×10¹⁸/cm³ or smaller, but is preferably doped with In and Mg in order to achieve increased crystallinity. By introducing In into second n type nitride semiconductor layer 14, the degree of supersaturation of holes can be reduced to result in increased crystallinity.

Further, second n type nitride semiconductor layer 14 preferably contains Mg. More preferably, second n type nitride semiconductor layer 14 contains Mg at an atomic concentration of not less than 5×10¹⁸/cm³ and not more than 1×10²⁰/cm³. When the atomic concentration thereof exceeds 1×10²⁰/cm³, the crystallinity may be deteriorated. On the other hand, when atomic concentration thereof is smaller than 5×10¹⁸/cm³, the effect of increasing the crystallinity cannot be obtained sufficiently.

(Light Emitting Layer)

In the present invention, light emitting layer 3 is preferably a nitride semiconductor containing at least one of Al, In, and Ga. More preferably, light emitting layer 3 has barrier layers and well layers provided alternately. Each of the barrier layers is made of GaN, and each of the well layers is made of a nitride semiconductor containing In. An optimum thickness of the well layer differs depending on wavelength of light emitted by the well layer, but preferably falls within a range of 2 nm to 20 nm.

For increased light emitting efficiency, light emitting layer 3 preferably has a multiquantum well structure. In the case where light emitting layer 3 includes such a plurality of well layers, at least one well layer functions as light emitting layer 3. Such a well layer is preferably made of InₚGa₁₋ₚN (0<p<1).

(P Type Nitride Semiconductor Layer)

In the present invention, p type nitride semiconductor layer 4 is constituted by a nitride semiconductor layer containing Al, In, or Ga. For p type nitride semiconductor layer 4, GaN, AlGaN, InAlGaN, or InGaN can be used, for example. Such a p type nitride semiconductor layer 4 may be doped with a p type impurity of Mg or Zn, or may be undoped.

Such a p type nitride semiconductor layer 4 may be constituted by a single layer or a plurality of layers. In the case where p type nitride semiconductor layer 4 is constituted by a plurality of layers, p type nitride semiconductor layer 4 may have a stacking structure such as InGaN/GaN, InGaN/AlGaN, AlGaN/GaN, or InGaN/InGaN.

(Current Diffusion Layer)

In the present invention, a current diffusion layer 5 is in contact with p type nitride semiconductor layer 4, and serves as an electrode having a property allowing light to pass therethrough. Current diffusion layer 5 may be made of any material without any particular limitation, but is preferably made of indium tin oxide (ITO) in view of functions, transparency, and the like of current diffusion layer 5.

(P-Side Electrode and N-Side Electrode)

In the present invention, a p-side electrode 6 and n-side electrode 7 are provided for external connection. Conventionally known electrodes can be used for these p-side electrode 6 and n-side electrode 7. For example, Ti, Al, Au, and the like can be used therefor. Further, each of p-side electrode 6 and n-side electrode 7 is not limited to a single layer but can have a multilayer structure.

Each of p-side electrode 6 and n-side electrode 7 is preferably made of a metal containing one or both of Ti and Al, or an alloy containing this metal. This leads to reduced operation voltage of the nitride semiconductor light emitting element.

N-side electrode 7 described above is formed on a surface of the second n type nitride semiconductor layer, which is exposed by selectively etching it using a photolithographic technique.

### EXAMPLE

The following describes the present invention more in detail with reference to an example, but the present invention is not limited to this.

In the present example, the nitride semiconductor light emitting element shown in FIG. 2 is fabricated in accordance with the following procedure. First, a sapphire substrate 21 is set in a metal organic chemical vapor deposition (MOCVD) device. Then, sapphire substrate 21 is set to have a temperature of 1000° C., and is thermally cleaned in a hydrogen atmosphere.

Next, sapphire substrate 21 is set to have a temperature of 500° C., and trimethylgallium (TMG) and ammonia (NH₃) are introduced to grow a low-temperature GaN buffer layer 31 having a thickness of 20 nm.

Then, sapphire substrate 21 is set to have a temperature of 1000° C., and TMG and NH₃ are introduced in the same way as above to grow an undoped GaN layer 32 having a thickness of 2 μm. With the temperature of sapphire substrate 21 being kept at 1000° C., trimethylindium (TMI), silane (SiH₄), and tetramethyl tin ((CH₃)₄Sn) are introduced in addition to TMG and NH₃, thereby growing a high-doped n-GaN layer 33 having a thickness of 3 μm.

Such a high-doped n-GaN layer 33 is adapted to have TMI at a concentration of 1×10²⁰/cm³, have SiH₄ at a concentration of 2×10¹⁹/cm³, and have (CH₃)₄Sn at a concentration of 2×10¹⁸/cm by adjusting amounts of supply of the raw materials. In this way, n type nitride semiconductor layer 22 constituted by low-temperature GaN buffer layer 31, undoped GaN layer 32, and high-doped n-GaN layer 33 is formed on sapphire substrate 21.

Then, the temperature of sapphire substrate 21 is decreased to 700° C., and then TMG and NH₃ are introduced to form a GaN barrier layer having a thickness of 10 nm. In addition to TMG and NH₃, TMI is then introduced to form an In_{0.2}Ga_{0.8}N well layer having a thickness of 2.5 nm. By forming such GaN barrier layers and such In_{0.2}Ga_{0.8}N well layers alternately in this way for six cycles, a light emitting layer 23 is grown on n type nitride semiconductor layer 22.

Then, sapphire substrate 21 is set to have a temperature of 950° C. and trimethylaluminum (TMA), TMG, NH₃, and dicyclopentadienyl magnesium (CP₂Mg) are introduced to form a p-Al_{0.2}Ga_{0.8}N layer having a thickness of 20 nm. Then, with the temperature of sapphire substrate 21 being maintained at 950° C., TMG and NH₃ are introduced to form a p-GaN layer having a thickness of 100 nm. In this way, a p type nitride semiconductor layer 24 constituted by the p-Al_{0.2}Ga_{0.8}N layer and the p-GaN layer is formed.

Thereafter, the temperature of sapphire substrate 21 is sufficiently decreased and sapphire substrate 21 is then brought out of the MOCVD device and is set in a sputtering device. Then, on p type nitride semiconductor layer 24, a current diffusion layer 25 having a thickness of 200 nm and made of ITO is formed.

Next, using the photolithographic technique, reactive ion etching (RIE) is selectively performed to expose a surface of high-doped n-GaN layer 33 from the surface of current diffusion layer 25. Then, on high-doped n-GaN layer 33 thus exposed by the etching, an n-side electrode 27 made of Ti/Al/Au is formed. A p-side electrode 26 made of Ti/Al/Au is formed on current diffusion layer 25. In this way, the nitride semiconductor light emitting element shown in FIG. 2 is fabricated.

High-doped n-GaN layer 33 of the nitride semiconductor light emitting element thus fabricated in the present example has Si at an atomic concentration of 2×10¹⁹/cm³, has In at an atomic concentration of 1×10²⁰/cm³, and has Sn at an atomic concentration of 2×10¹⁸/cm³. This leads to a nitride semiconductor with high crystallinity, reduced resistivity, and low operation voltage of the nitride semiconductor light emitting element.

The nitride semiconductor light emitting element described above in the preferred embodiment of the present invention is not limited to the above, and may be configured in a manner different from the above.

According to the present invention, a high-quality n type nitride semiconductor layer can be obtained which can be applied to electronic devices such as a light emitting diode and a laser diode.

Heretofore, the embodiment and example of the present invention have been illustrated, but it has been initially expected to appropriately combine features of the embodiment and example.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride semiconductor light emitting element comprising:
an n type nitride semiconductor layer formed on a substrate;
a light emitting layer formed on said n type nitride semiconductor layer; and
a p type nitride semiconductor layer formed on said light emitting layer,
said n type nitride semiconductor layer being constituted by one layer or two or more stacked layers,
at least one layer constituting said n type nitride semiconductor layer containing Si and Sn as n type dopants and containing In as an isoelectronic dopant.

2. The nitride semiconductor light emitting element according to claim 1, wherein said at least one layer constituting said n type nitride semiconductor layer contains Si at an atomic concentration of not less than 5×10¹⁸/cm³ and not more than 1×10²⁰ /cm³.

3. The nitride semiconductor light emitting element according to claim 1, wherein said at least one layer constituting said n type nitride semiconductor layer contains Sn at an atomic concentration of not less than 5×10¹⁷/cm³ and not more than 1×10¹⁹/cm³.

4. The nitride semiconductor light emitting element according to claim 1, wherein said at least one layer constituting said n type nitride semiconductor layer contains In at an atomic concentration of not less than 5×10¹⁹/cm³ and not more than 1×10²¹/cm³.

5. The nitride semiconductor light emitting element according to claim 1, wherein said at least one layer constituting said n type nitride semiconductor layer contains Sn at an atomic concentration smaller than that of Si.

6. The nitride semiconductor light emitting element according to claim 1, wherein said at least one layer constituting said n type nitride semiconductor layer is GaN.

7. The nitride semiconductor light emitting element according to claim 1, wherein said n type nitride semiconductor layer is a contact layer in contact with an n-side electrode.

8. The nitride semiconductor light emitting element according to claim 7, wherein said n-side electrode is made of a metal containing one or both of Ti and Al, or is made of an alloy containing said metal.

9. The nitride semiconductor light emitting element according to claim 1, wherein said n type nitride semiconductor layer includes a first n type nitride semiconductor layer, and a second n type nitride semiconductor layer formed between said first n type nitride semiconductor layer and said light emitting layer, and said second n type nitride semiconductor layer contains the n type dopants at atomic concentrations smaller than those of the n type dopants contained in said first n type nitride semiconductor layer.

10. The nitride semiconductor light emitting element according to claim 9, wherein said second n type nitride semiconductor layer contains In as an isoelectronic dopant.

11. The nitride semiconductor light emitting element according to claim 9, wherein said second n type nitride semiconductor layer contains Mg.

12. The nitride semiconductor light emitting element according to claim 9, wherein said second n type nitride semiconductor layer contains Mg at an atomic concentration of not less than 5×10¹⁸/cm³ and not more than 1×10²⁰/cm³.
